(19) United States
(12) Patent Application Publication
(10) Pub. No.: US 2024/0125854 A1
(43) Pub. Date: Apr. 18, 2024

(54) ELECTROCHEMICAL CELL CHARACTERISATION

(71) Applicant: Cirrus Logic International Semiconductor Ltd., Edinburgh (GB)

(72) Inventors: John P. LESSO, Edinburgh (GB); Scott P. WARRICK, Austin, TX (US); Yanto SURYONO, Tokyo (JP)

(73) Assignee: Cirrus Logic International Semiconductor Ltd., Edinburgh (GB)

(21) Appl. No.: 18/452,100

(22) Filed: Aug. 18, 2023

Related U.S. Application Data
(60) Provisional application No. 63/413,022, filed on Oct. 4, 2022.

(51) Int. Cl. G01R 31/36; G01R 31/367; G01R 31/382

(52) U.S. Cl. CPC G01R 31/3648; G01R 31/367; G01R 31/382

(57) ABSTRACT

Circuitry for processing a response from an electrochemical cell to a stimulus, the circuitry comprising: sense circuitry configured to measure the response of the electrochemical cell to the stimulus; and processing circuitry configured to: sample the measured response to obtain a plurality of samples; and determine a first average signal based on a first number of samples of the plurality of samples; and output the first average signal, wherein the first number of samples in the first average signal is selected to minimise a first variance in the first number of samples.

### TECHNICAL FIELD

The present disclosure relates to circuitry for measuring characteristics in electrochemical sensors.

### BACKGROUND

Electrochemical sensors are widely used for the detection or characterisation of one or more particular chemical species, analytes, as an oxidation or reduction current (or voltage in the case of potentiometric sensors). Such sensors comprise an electrochemical cell, consisting of two or more electrodes configured for contact with an analyte whose concentration is to be ascertained. Such sensors also comprise circuitry for driving one or more of the electrodes and for sampling a response signal at one or more of the electrodes. The sampled response signal can be processed to determine a concentration of an analyte.

When such circuitry is battery powered, for example when an electrochemical sensor is integrated into a wearable device, it is desirable for the sensor to be as small as possible and use as little power as possible. Power consumption can be reduced by reducing the sampling frequency of the electrochemical cell. However, reducing sampling frequency can lead to measurement inaccuracies and reductions in signal-to-noise ratio (SNR).

### SUMMARY

According to a first aspect of the disclosure, there is provided circuitry for processing a response from an electrochemical cell to a stimulus, the circuitry comprising: sense circuitry configured to measure the response of the electrochemical cell to the stimulus; and processing circuitry configured to: sample the measured response to obtain a plurality of samples; and determine a first average signal based on a first number of samples of the plurality of samples; and output the first average signal, wherein the first number of samples in the first average signal is selected to minimise a first variance in the first number of samples.

The first number of samples may be dynamically adjusted to minimize the first variance in the first number of samples.

The processing circuitry may be configured to repeat the steps of sampling, determining, and outputting such that the first average signal is calculated periodically. The first number of samples used to determine the first average signal may also be selected periodically. In which case, a time period between updates of the first number of samples is preferably longer than a time period between repetitions of the steps of sampling, determining, and outputting. For example, the first number of samples over which the first average signal is calculated may be updated every half an hour or hour, that value for the first number of samples used for determining the first average value until the next update of the first number of samples.

The processing circuitry may be configured to, in parallel to determining the first average signal, determine one or more second average signals based on one or more second numbers of samples of the plurality of samples, the first number of samples and the one or more second number of samples being different; and determine a respective second variance in each of the one or more second numbers of samples. The first number of samples may be selected from the first number of samples and the one or more second number of samples, the first variance being lower than each respective second variance.

The processing circuitry may further comprise: a first processing block configured to determine the first average signal and the first variance in the first number of samples; and one or more second processing blocks, each second processing block configured to determine a respective one of the second average signals and a respective one of the second variances. One or more of the first average signal and second average signals (determined by the first processing block or the one or more second processing blocks) may be used by others of the first processing block or the one or more second processing blocks for determining a respective first variance or second variance.

The stimulus may comprise a step signal or an impulse signal.

The processing circuitry may comprise further processing circuitry configured to determine a characteristic of the cell based on the first average signal. The further processing circuitry may be configured to determine, based on the determined characteristic, one or more of the following: an optimum bias voltage to be applied to the electrochemical cell during sensing of an analyte; a quality of an electrolyte in the electrochemical cell; a fault at the electrochemical cell; a condition of the electrochemical cell; determine one or more offsets for subsequent processing; an equivalent circuit model (ECM) for the electrochemical cell.

The condition may comprise one or more of: ageing of the electrochemical cell; a change in temperature at the electrochemical cell; and a change in pressure at the electrochemical cell.

A sample rate or other characteristic of the further processing circuitry may be adjusted based on the first number of samples.

A characteristic of the further processing circuitry may be adjusted based on the first number of samples.

The first number of samples may be selected using a trained neural network.

The electrochemical cell may be an electrochemical sensor. The stimulus may be a stimulus voltage. The measured response may be a response current.

The processing circuitry may comprise an analog-to-digital converter (ADC) configured to obtain the plurality of samples.

The circuitry may further comprise drive circuitry configured to apply the stimulus to the electrochemical cell. The drive circuitry may comprise a digital-to-analog converter configured to generate the stimulus responsive to a digital input signal.

The electrochemical cell may comprise a first electrode and at least one second electrode. The drive circuitry may be configured to apply the stimulus to the first electrode. The sense circuitry may be configured to measure the response at the at least one second electrode.

The electrochemical cell may comprise one of an amperometric sensor, a potentiometric sensor and a battery. The amperometric sensor may comprise a potentiostat, wherein the first electrode comprises a counter electrode of the potentiostat, and wherein the at least one second electrode comprises a working electrode of the potentiostat.

According to another aspect of the disclosure, there is provided a system comprising the circuitry described above; and the electrochemical cell.

According to another aspect of the disclosure, there is provided an electronic device, comprising the circuitry of any one of claims 1 to 20 or the system of claim 21.

The device may comprise one of an analyte monitoring device or an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

According to another aspect of the disclosure, there is provided a method of processing a response from an electrochemical cell to a stimulus, the method comprising: measuring the response of the electrochemical cell to the stimulus; and sampling the measured response to obtain a plurality of samples; and determining a first average signal based on a first number of samples of the plurality of samples; and outputting the first average signal, wherein the first number of samples in the first average signal is selected to minimise a first variance in the first number of samples.

Throughout this specification the word “comprise”, or variations such as “comprises” or “comprising”, will be understood to imply the inclusion of a stated element, integer or step, or group of elements, integers, or steps, but not the exclusion of any other element, integer or step, or group of elements, integers or steps.

### BRIEF DESCRIPTION OF DRAWINGS

Embodiments of the present disclosure will now be described by way of non-limiting examples with reference to the drawings, in which:

FIG. 1 illustrates a schematic diagram and electrical equivalent circuit for a three-electrode electrochemical cell;

FIG. 2 is a schematic diagram of an example prior art measurement circuit;

FIG. 3 is a graph of variance vs sampling time for an electrochemical sensor;

FIG. 4 is a schematic diagram of an example measurement circuit for characterising an electrochemical cell;

FIG. 5 is a graphical illustration of signal flow of an example approach to calculating Allen variance;

FIG. 6 is an example implementation of the processing circuitry of FIG. 4;

FIG. 7 is an example implementation of the processing circuitry of FIG. 4;

FIG. 8 is an example implementation of the processing circuitry of FIG. 4;

FIG. 9 is an example implementation of the processing circuitry of FIG. 4; and

FIG. 10 is an example implementation of the processing circuitry of FIG. 4.

### DESCRIPTION OF EMBODIMENTS

Electrochemical sensors are widely used for the detection of one or more particular chemical species, analytes, as an oxidation or reduction current. Such sensors comprise an electrochemical cell, consisting of two or more electrodes configured for contact with an analyte whose concentration is to be ascertained. Such sensors also comprise circuitry for driving one or more of the electrodes and for measuring a response at one or more of the electrodes. Batteries also comprise one or more electrochemical cells which typically consist of two or more electrodes (e.g., an anode and a cathode) configured for contact with a conductive electrolyte. Characteristics of batteries may be ascertained using drive and measurement circuitry similar to that used for characterising electrochemical cells in electrochemical sensors.

Measurements made by measurement circuitry used to characterise electrochemical cells are typically sampled using an analog-to-digital converter or similar. In doing so, a trade-off made between power consumption and quality of measurements obtained. For example, increasing a time period between samples may reduce power consumption to the detriment of quality of signals obtained.

Embodiments of the present disclosure provide novel circuitry for processing electrochemical cells and systems (such as sensors, batteries, and the like) into which electrochemical cells are incorporated. Specifically, embodiments of the present disclosure relate to novel techniques for improving measurements made using chronoamperometry.

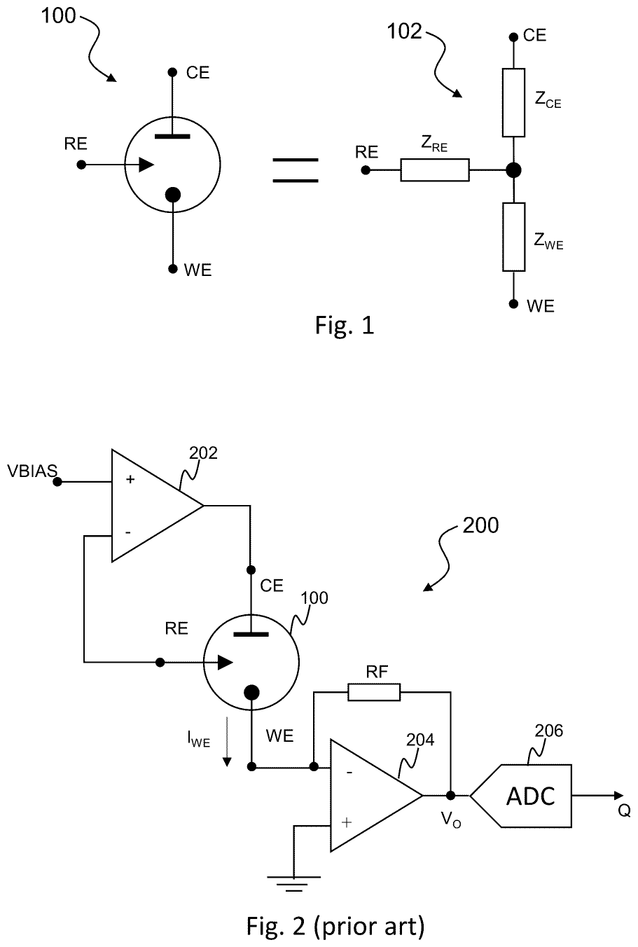

FIG. 1 is a schematic diagram of an example electrochemical cell 100 comprising three electrodes, namely a counter electrode CE, a working electrode WE and a reference electrode RE. FIG. 1 also shows an equivalent circuit 102 for the electrochemical cell comprising a counter electrode impedance ZCE, a working electrode impedance ZWE and a reference electrode impedance ZRE. Embodiments of the disclosure will be described with reference to this example electrochemical cell 100. It will be appreciated, however, that the techniques and apparatus described herein may be used in conjunction with any conceivable electrochemical system, including but not limited to two-electrode electrochemical cells (e.g., cells comprising a counter electrode CE and a working electrode WE and no reference electrode), or electrochemical cells with more than three electrodes. Electrodes of the electrochemical cells described herein may also be referred to as anodes and/or cathodes as is conventional in the field of electrical batteries.

To determine a characteristic of the electrochemical cell 100, and therefore an analyte concentration, a bias voltage is applied at the counter electrode CE and a current at the working electrode WE is measured. The reference electrode RE is used to measure a voltage drop between the working electrode WE and the reference electrode RE. The bias voltage is then adjusted to maintain the voltage drop between RE and WE constant. As the resistance in the cell 100 increases, the current measured at the working electrode WE decreases. Likewise, as the resistance in the cell 100decreases, the current measured at the working electrode WE increases. Thus the electrochemical cell 100 reaches a state of equilibrium where the voltage drop between the reference electrode RE and the working electrode WE is maintained constant. Since the bias voltage at the counter electrode CE and the measured current at WE are known, the resistance of the cell 100 can be ascertained.

FIG. 2 illustrates an example prior art drive and measurement circuit 200 which is configured to implement the above explained cell characterisation, specifically for measuring an analyte concentration in the electrochemical cell 100 shown in FIG. 1. The circuit 200 comprises a first amplifier 202 and a second amplifier 204. Each of the first and second amplifiers 202, 204 may comprise one or more op-amps. A non-inverting input of the first amplifier 202 is coupled to a bias voltage VBIAS which may be generated by a digital-to-analog converter DAC (not shown). An inverting input of the first amplifier 202 is coupled to the reference electrode RE. An output of the first amplifier 202 is coupled to the counter electrode CE and configured to drive the counter electrode CE with a counter electrode bias voltage VCE. The counter electrode bias voltage VCE applied at the counter electrode CE by the first amplifier 202 is proportional to the difference between the bias voltage VBIAS and the voltage VRE at the reference electrode RE. As such, the first amplifier 202 acts to maintain the voltage between the reference electrode RE and the working electrode WE at the bias voltage VBIAS. An inverting input of the second amplifier 204 is coupled to the working electrode WE and a non-inverting input of the second amplifier 204 is coupled to a fixed reference voltage, in this case ground GND. A feedback resistor RF is coupled between the non-inverting input and an output of the second amplifier 204. As such, the second amplifier 204 may operate as a transimpedance amplifier. The second amplifier 204 is thus operable to output a voltage VO which is proportional to the current IWE at the working electrode WE. The output voltage VO is then provided to an analog-to-digital converter (ADC) 206 which samples the output voltage VO and outputs a digital output Q which represents the current IWE at the working electrode WE.

To bias the counter electrode CE, and therefore the electrochemical cell 100, at different voltages, the bias voltage VBIAS may be adjusted. The bias voltage VBIAS may be adjusted between a reference voltage (e.g. ground or zero volts) and the supply voltage VDD. With the non-inverting input of the second amplifier 204 is set at VDD/2, a positive bias may be applied to the cell 100 by maintaining the bias voltage VBIAS above VDD/2. Likewise, a negative bias may be applied to the cell 100 by maintaining the bias voltage VBIAS below VDD/2.

In the example shown in FIG. 2, the cell 100 is in the form of an amperometric sensor. As such, the stimulus applied for CA is a voltage stimulus and the measured response is a current. In other embodiments, a potentiometric sensor or battery may be characterised using CA by applying a current stimulus and measuring a voltage response of the cell(s) comprised in the sensor or battery. In either case, an ADC, such as the ADC 206 is provided to which samples an output signal to generate a digital output Q comprising a plurality of samples of the output signal.

It is common for electrochemical cells, such as the cell 100 shown in FIG. 2, to be used in power sensitive devices, such as those powered by batteries (e.g. wearable (e.g. medical) devices). In such devices, it is desirable to minimise power consumption. One way to reduce power consumption is to reduce the frequency of sampling of the electrochemical cell. For example, a mean output from the cell can be obtained by averaging samples output from the ADC over a time period τ. Power consumption can be reduced by extending the time period τ. By extending the time period τ, processing and transmission of the mean output may occur less often, thereby reducing power consumption. It will be appreciated, however, that reducing the frequency of sampling of the cell (e.g. by extending the time period τ across which the mean output is obtained) can impact the accuracy of measurements and/or increase latency which may lead to loss of information regarding characteristics of the cell over time.

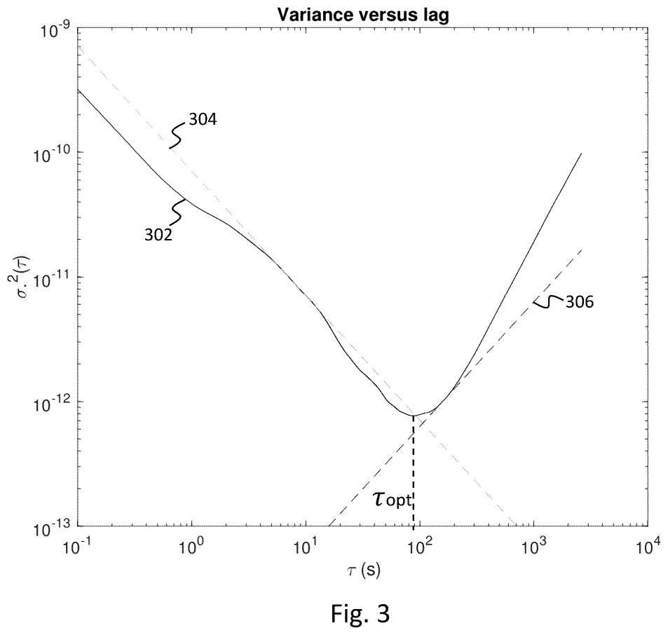

FIG. 3 is a graph which plots (line 302) the time period τ over which a mean output is obtained for a typical electrochemical cell, such as the cell 100 shown in FIG. 2, vs variance of samples used to obtain the mean output. It can be seen that as the time period increases from zero, the variance decreases to a minima where τ=τopt (around 190 seconds). This decrease in variance is due to a decrease in white noise 304. From this point, the variance increases due to an increase in Brownian (or red) noise 306 (due to the time period r over which the mean output is obtained increasing).

Thus it can be seen that there is an optimum time τopt over which a mean output may be obtained which minimises both white and Brownian noise associated with the cell 100 (and thus the variance between samples from which the mean output is calculated). It will also be appreciated that this optimum time topt may vary over time.

Thus, embodiments of the present disclosure implement various sampling control strategies in which an optimum time period τopt is derived which minimises a variance in samples over the time period τopt, those samples used to calculate the mean output.

In some embodiments, the noise spectrum of the cell 100 may be estimated to obtain the optimum sampling time period topt. For example, an Allan variance may be used to quantify noise associated with the cell 100 or sensor encompassing the cell 100. The use of Allan variance may provide several advantages when compared to other techniques, such as Fourier methods. For example, Allan variance has good resolution at low frequencies, i.e. large sampling time periods (or lags). As such, Allan variance lends itself to measurements averaged over long time frames without the need to explicitly deal with coherent/incoherent processes and/or stationary/non-stationary processes. This is in contrast to direct fast Fourier transform (FFT) approaches for quantifying noise associated with the cell 100. In such approaches, both coherent and incoherent FFTs would need to be computed and the results analysed and combined to make a final determination. In contrast, when using Allen variance, the output of such calculations provides an optimum sampling time without the need for further processing. Another advantage is that use of Allan variance enables the calculation of a timescale over which a random process (such as noise) can be assumed to be stationary. Up to that time, averaging can be expected to give a better estimate of mean or average. Averaging over longer time periods (i.e. when the random process can no longer be assumed to be stationary) will not provide the desired estimate of mean and in many cases will cause the variance of samples to diverge.

Thus, by tracking Allan variance, the optimum sampling time r over which to obtain the mean output of the cell 100, can be calculated and adjusted (e.g. dynamically).

The 2-zample non-overlapped Allan variance may be defined as the squared difference of averages, as shown below:

σ²(N)= [symbol] (θ̅ₙ̅₊̅₁̅+(θ̅ₙ̅)²

[symbol]

The above may be approximated using a more computationally efficient estimate using the Wiener-Khinchin theorem to relate the variance and autocorrelation of θ̅ₙ̅ to its two-sided power spectral density (PSD). This allows the Allan variance to be related to the PSD P(f), giving the following equation:

$${σ}^{2} ( τ ) = 4 {\int }_{0}^{∞} P ( f ) \frac{{sin}^{4} ( π f τ )}{{( π f τ )}^{2}} df$$

Thus, from the above equation, sensor noise can be quantified to optimise the time period τ over which the mean output is obtained, thus minimizing sample-to-sample variance in the mean output MO.

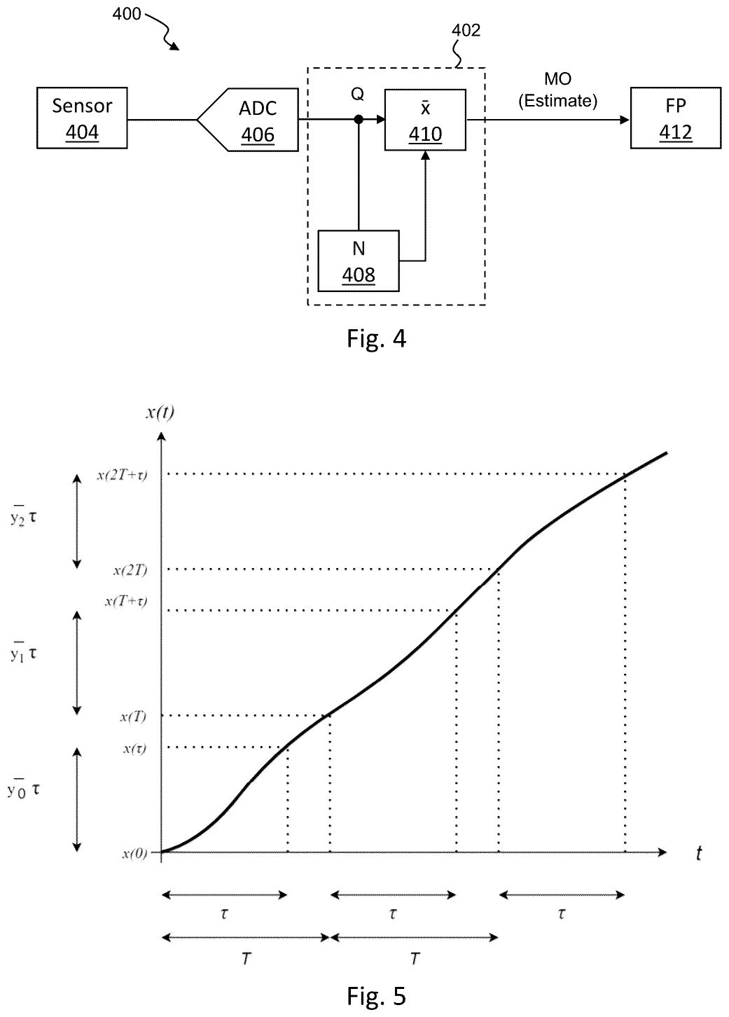

FIG. 4 is a schematic illustration of a system 400 comprising processing circuitry 402 for obtaining an estimate of the mean output of a sensor 404. The system comprises the sensor 404, which may for example comprise the cell 100 shown in FIG. 2, and an ADC 406, such as the ADC 206 shown in FIG. 2. The system 400 may optionally further comprise further processing (FP) circuitry 412, which may be provided locally or remote to the processing circuitry 402.

The sensor 404 may further comprise drive and/or measurement circuitry for interrogating the cell 100 and/or measuring a response of the cell 100 to such interrogation. As such, the sensor 404 may output an output signal (e.g. a voltage VO or current 10) to the ADC 406 which represents a characteristic of the cell 100. The ADC 406 may then be configured to output to the processing circuitry 402 a digital representation Q of the output signal provided by the sensor 404.

The processing circuitry 402 may comprise a sample control module 408 and an averaging module 410. The output signal Q from the ADC 406 is provided to the averaging module 410 which is configured to calculate the mean (or other average) MO of a number N of samples of the output signal Q. This mean MO represents an estimate of the measured response over the time period r spanning the N samples of the output signal Q.

The averaging operation may be performed in any conceivable manner. For example, a moving average may be used. For example, if a single measurement is generated every five minutes, the moving average may be obtained for 20 samples (i.e. in the previous 100 minutes) and updated every five minutes (e.g. on receipt of each new measurement sample from the ADC 406. In another example, a continuous average may be performed. In another example, an ensemble average may be performed. Other derived statistic may equally be used as the mean output MO, such as a median.

The number N of samples (or the time period spanning the N samples) of the output signal Q used to derive the mean output MO may be controlled (e.g. dynamically) based on a signal provided by the sample control module 408. The sample control module 408 may receive the output signal Q from the ADC 406 and determine the number N of samples to minimise the effects of noise in the sensor 404 on the mean output MO. This may be achieved by minimising the variance of the N samples upon which the mean output MO is calculated.

The sample control module 408 may be configured to determine the number N of samples (or the time period τ) by calculating a variance, such as an Allen variance, in samples of the output signal Q. The samples used to obtain the Allen variance may comprise all N samples in a subset of samples, or alternatively a subset of each subset. For example, the variance may be calculated using M samples of the N samples in each subset.

In one example, the Allan variance may be determined as follows for M samples of the N samples of a subset.

$$\begin{matrix}{σ}_{y}^{2} ( M , T , τ ) = \frac{1}{M - 1} \{ {\sum }_{i = 0}^{M - 1} \overline{{y}_{i}^{2}} - {\frac{1}{M} [ {\sum }_{i = 0}^{M - 1} \overline{{y}_{i}} ]}^{2} \} \\ = \frac{1}{M - 1} \{ {\sum }_{i = 0}^{M - 1} [ \frac{x ( iT + τ ) - x ( iT )}{τ} ] - \\ {\frac{1}{M} [ {\sum }_{i = 0}^{M - 1} \frac{x ( iT + τ ) - x ( iT )}{τ} ]}^{2} \}\end{matrix}$$

Where x(t) is the integration of y(t), i.e.:

x(t)=∫_{τ=0}^{t}y(τ)dτ

Therefore, the Allan variance is the variance of an M-sample population having an average value of y(y̅) over time span τ, where each sample is separated by time T.

It will be appreciated that the processing circuitry 402 may be configured to determine either a sample time T or a value for N (i.e. number of samples used for calculation of the mean output MO) or both. The processing circuitry 402 may be configured to perform a conversion between sample time T and sample number N, depending on the specific implementation of the processing circuitry 402, various of which are described below.

The processing circuitry 402 may be configured to determine one or more of the variance, the sample time T and/or a value for N continuously. Alternatively, such determinations may be made periodically. For example, the measurement of variance may be made once per 30 minutes or once per hour. A measurement of variance may be made and used to determine the optimum sample time T and/or a value for N for the following period until the next measurement of variance is made. The optimum sample time T and/or a value for N may be determined/updated multiple times between measurements of variance.

The output of processing circuitry 402 represents an estimate of the current from the cell 100, which can then be used to estimate one or more characteristics of the cell, such as one or more analyte concentrations. Further processing (FP) circuitry 412 may be configured to determine such characteristics.

The FP circuitry 412 may comprise a digital signal processor (DSP), an application processor (AP) or the like. Additionally or alternatively, the FP circuitry 412 may implement one or more neural networks which may be trained on data pertaining to the sensor 404 and/or the cell 100.

The determined characteristics may comprise, for example, a resistance or impedance of the sensor 404 or the cell 100. Based on the determined characteristics, one or more properties of the device or operating parameters may be obtained. For example, the FP processing circuitry may determine an optimum bias voltage to be applied to the electrochemical cell 100 during sensing of an analyte. Additionally or alternatively, a quality of an electrolyte in the electrochemical cell 100 may be ascertained. Additionally or alternatively, a fault at the electrochemical cell 100 and/or sensor 404 may be ascertained. Additionally or alternatively, the FP circuitry 412 may be configured to determine one or more offsets for subsequent processing. Additionally or alternatively, an equivalent circuit model (ECM) for the electrochemical cell 100 may be ascertained. Additionally or alternatively, a condition of the electrochemical cell 100 may be ascertained. Such a condition may comprise one or more of: ageing of the cell 100, a temperature (or change or temperature) at the cell 100 or sensor 404, or a change in pressure at or in the cell 100.

It will be appreciated that a change in sample time T (and sample number N) may affect downstream processing, such as that performed by the FP circuitry 412. For example, if the sample time T is reduced, a sampling rate of the FP circuitry 412 may need to be increased to account for this reduction in sample time T. Likewise, to conserve power, a sampling rate of the FP circuitry 412 may be reduced in response to an increase in the sample time T. As such, the FP circuitry 412 may be configured to process the mean output MO in dependence on the sample time T (and/or sample number N) chosen. For example, based on the sample number N, processing of the mean output MO may require adjustment of one or more parameters of an algorithm implemented by the FP circuitry 412, or the change in of characteristics of the FP circuitry 412 (e.g. DSP and/or AP). In some embodiments, a sample rate of one or more elements of the FP circuitry 412 may be adjusted in dependence on the sample number N and/or sample time T used for obtaining the mean output MO.

It will also be appreciated that whilst the sample time T may allow for a maximum number of mean output MO samples to be output from the processing circuitry 402, the processing circuitry 402 may be configured to output fewer than this maximum number of mean output MO samples, for example to conserve power. Equally, the FP circuitry 412 may be configured to sample the mean output MO at a rate which is lower than that at the output of the processing circuitry 402.

FIG. 5 is a graphical illustration of signal flow of an example approach to calculating Allen variance which is a direct implementation of the equations below.

Accordingly:

$$\overline{{y}_{n}} = \frac{x ( iT + τ ) - x ( iT )}{τ}$$

In one non-limiting example, the Allan variance may be defined based on a sample size of 2, i.e. M=2 and by equating the time period between samples T and the time span τ (which is true where there is no overlap or gap between sample periods). In doing so, the Allan variance can be simplified to the following equation.

$${σ}_{y}^{2} ( τ ) = \frac{1}{2 {τ}^{2}} 〈 {( {x}_{n + 2} - 2 {x}_{n + 1} + {x}_{n} )}^{2} 〉$$

In the above example, the Allan variance is provided in the time domain. However, it is also possible to calculate the Allan variance in the frequency domain. Suppose the frequency domain representation of noise y(t) is Y(f). The total power of noise y(t) gives its expected variance, which may be defined as follows:

σ²∫₀^{∞}Y(f)df

When Y(f) ls filtered with a transfer function H(f), the variance becomes:

σ_{H}²∫₀^{∞}Y(f)H(f)df

The process of calculating Allan variance of the digital representation may be broken up into multiple smaller processing steps in the interest of computational efficiency. The following table provides an example set of processing steps for determining the Allan variance:

| | | Equivalent | |
|---|---|---|---|
| | | Signal | |
| | Process | Processing | Transfer Function |
| ϕ_{0,n} = y(t)\|ₜ₌ₙ | Sampling | ZOH at frequency 1 | $\vert {Φ}_{0 , n} \vert = \vert \frac{sin ( \frac{ω}{2} )}{( \frac{ω}{2} )} \vert$ |
| ϕ_{1,n} = yₙ | Averaging of N samples | 1^{st} order CIC with Decimation ratio R = N | $\vert {Φ}_{1 , n} \vert = \frac{1}{N} \vert \frac{sin ( \frac{ω N}{2} )}{sin ( \frac{ω}{2} )} \vert \vert {Φ}_{0 , n} \vert$ |
| ϕ_{2,n} = ϕ_{1,n+1} − ϕ_{1,n} | Subtraction | Differentia- tion | Φ_{2,n} = Φ_{1,n} (z − 1) $\vert {Φ}_{2 , n} \vert = 2 \vert {Φ}_{1 , n} \vert \vert sin ( \frac{ω N}{2} ) \vert$ |
| ${ϕ}_{3 , n} = \frac{1}{2} {ϕ}_{2 , n}^{2}$ | Half of Square | Simple arithmetic | $\vert {Φ}_{3 , n} \vert = \frac{1}{2} {\vert {Φ}_{2 , n} \vert}^{2}$ |

Starting with the process of sampling referred to in the above table, a zero-order hold (ZOH) at a first frequency may be performed. To obtain an average of N samples, a 1^{st} order cascaded integrator comb (CIC) filter or other finite impulse response (FIR) filter may be used. The decimation ratio R of the CIC filter may be set to R=N (i.e. the number of samples). The subtraction function may be performed by differentiation. The half of square function may be implemented using simple arithmetic processes.

Thus, the equivalent filter which may be applied to each sample of the digital

representation Q would have the following transfer function:

$${H}_{A} ( ω ) = \frac{1}{2} \cdot \frac{4}{{τ}^{2}} {\vert \frac{sin ( \frac{ω N}{2} )}{sin ( \frac{ω}{2} )} \vert}^{2} {\vert \frac{sin ( \frac{ω}{2} )}{( \frac{ω}{2} )} \vert}^{2} {\vert sin ( \frac{ω N}{2} ) \vert}^{2} = \frac{2}{{τ}^{2}} \frac{{sin}^{4} ( \frac{ω N}{2} )}{{( \frac{ω}{2} )}^{2}}$$

Hence, the Allan variance may be defined as follows:

$${σ}_{A}^{2} ( N ) = \frac{2}{{N}^{2}} {\int }_{0}^{∞} Y ( f ) \frac{{sin}^{4} ( π Nf )}{{( π f )}^{2}} df$$

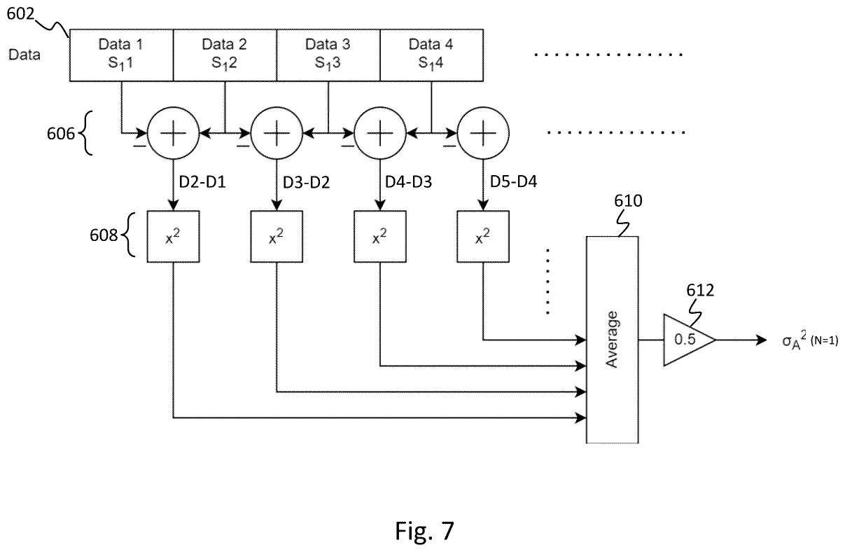

A practical implementations for the determination of the Allan variance, which may be implemented by the sample control module 408 of FIG. 4, is depicted in FIG. 7.

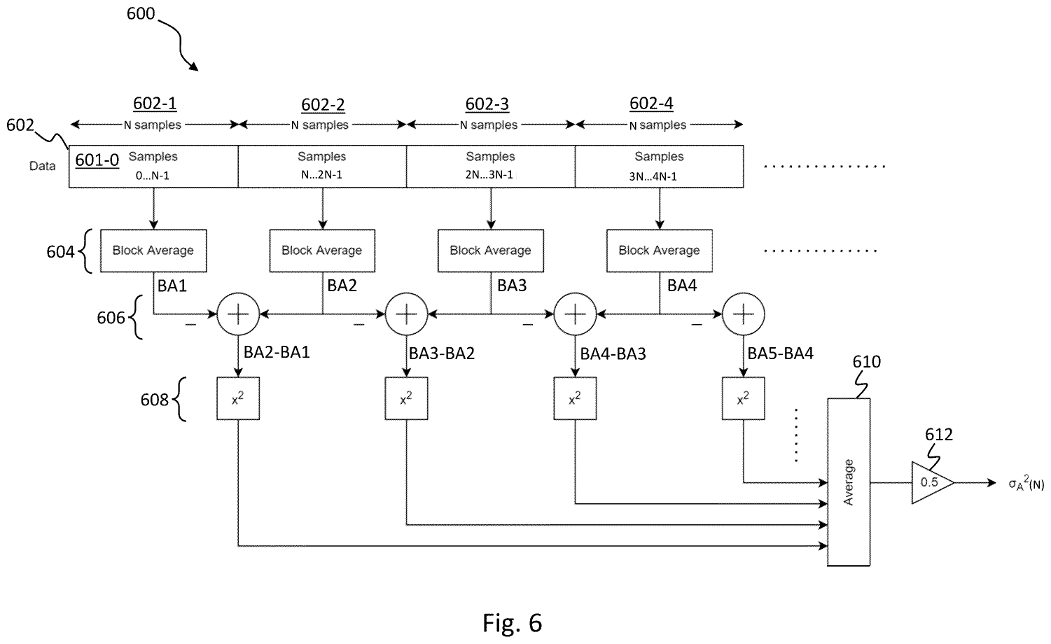

Referring to FIG. 6, a process 600 is shown for implementing the operations shown in the above table for obtaining the Allan variance in sample subsets of the digital representation Q. The digital representation (or data) Q comprises a stream 602 of samples which may be separated into subsets of N samples. For simplicity, four of the subsets are shown in FIG. 6. It will be appreciated that the present disclosure extends to there being as few as two subsets or more than four subsets. For each of the subsets of τ samples, a block average 604 is calculated. Each block average BA1:BA4 is subtracted from the previously calculated block average (i.e. for the preceding subset of samples in the data stream) at a subtraction block 606. The result of each subtraction is then squared by a square operator 608. A running average 610 is then obtained before a divide by two operation 612 is performed to obtain the Allan variance for that particular sample size N (and corresponding sample time τ).

As noted with reference to FIG. 3, the value of N (i.e. the number of samples in each subset) will affect the variance (and therefore noise). As such, the example process 600 shown in FIG. 6 may be repeated for multiple subset sample sizes (i.e. multiple values of N (and corresponding sample time τ). In some embodiments, the process 600 may be carried out for all values of N or τ to be considered.

Once values for Allan variance for each of sample size N have been obtained, the sample control module 408 may be configured to determine a variance minima of all the calculated variances (i.e. for all values of N to be considered). The corresponding value of N (or sample time τ) which provides the lowest variance may then be provided to the averaging module mean output MO calculated by the averaging module 410.

It will be appreciated that whilst each subset comprises N samples, in some embodiments, the Allan variance may be calculated based on a subset of M samples. For example, if each subset comprises 100 samples, then the Allan variance may be calculated based on, e.g. 2 or 10 or 20 or 50 of those samples.

To simplify operation of the processing circuitry 400, the number of samples N (and therefore the corresponding sample periods τ) may be constrained to a small subset of values. For example, the number of samples N may be constrained to be powers of two numbers, such as powers of 2, (e.g. N=2^{x}, x=0,1,2 . . . ). So, for example, to obtain a range of variance values for sample sizes up to 32768 samples, only 16 points (i.e. 16 variance calculations) need to be evaluated.

FIGS. 7 to 9 show an example implementation of such a regime.

Starting from FIG. 7, the data stream 602 is split into subsets of one sample. With a sample size of N=2⁰=1, the block average size becomes 1, such that the average is the sample value itself. As such, each subset of one sample is provided directly to the subtraction block 606.

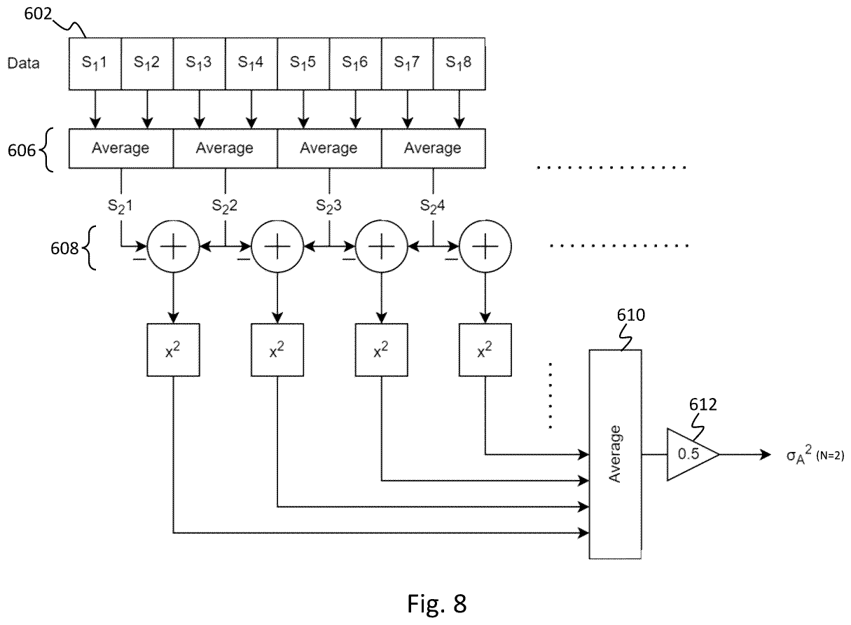

Referring to FIG. 8, the data stream 602 is split into subsets of two samples (sample size of N=2¹=2).

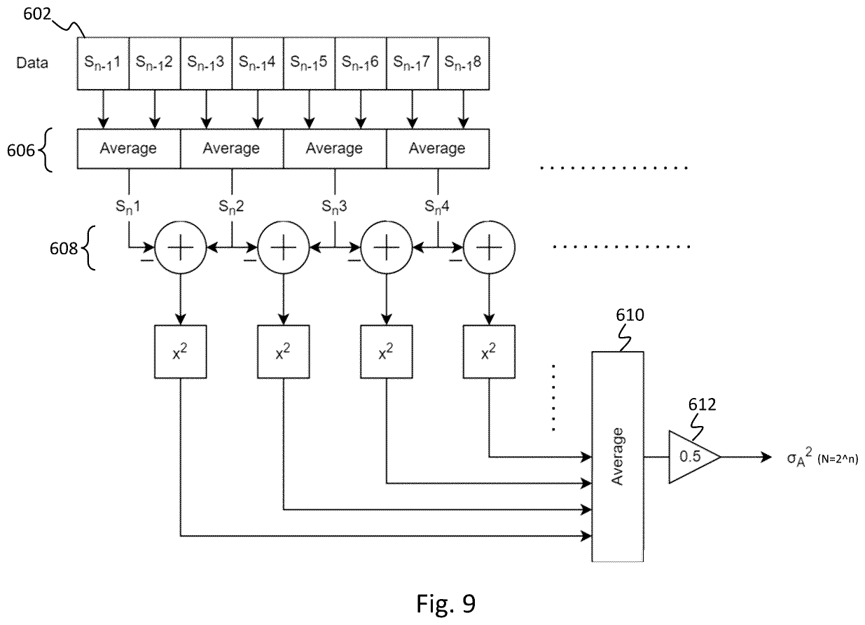

Referring to FIG. 9, the calculation can be extended to larger sample sizes, in general, to generate a variance for N=2ⁿ using samples of N=2ⁿ⁻¹.

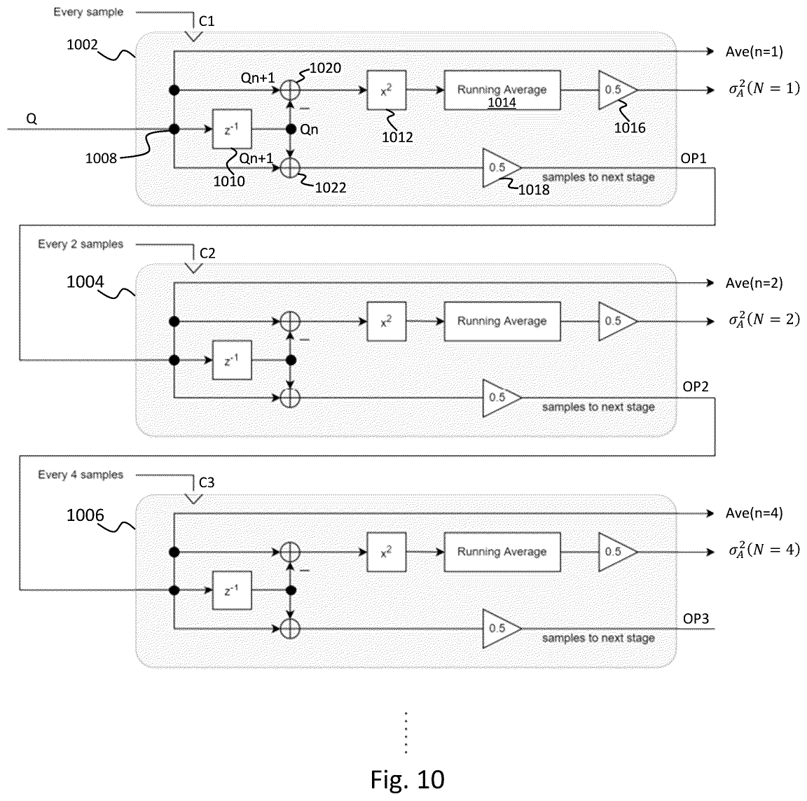

The processing circuitry 400 may be implemented using a computationally efficient hardware structure as illustrated in FIG. 10.

FIG. 10 illustrates an example processing architecture 1000 which may be implemented by the sample control module 408. The architecture 1000 comprise first, second and third processing blocks 1002, 1004, 1006 which may each be configured to implement the process described with reference to FIG. 6. The architecture 1000 may comprise additional processing blocks (not shown) or fewer processing blocks, depending on the range of subset sample sizes N to be calculated. For simplicity, in this example, only three processing blocks 1002, 1004, 1006 are shown in FIG. 10.

The first, second and third processing blocks 1002, 1004, 1006 are configured to calculate Allan variances for subset sample sizes of 2⁰, 2¹ and 2² respectively. Each of the first, second and third processing blocks 1002, 1004, 1006 are configured to receive a respective clock signal F1, F2, F3 via a respective clock input C1, C2, C3. As will be explained in more detail below, the first, second and third clock signals F1, F2, F3 have the relationship F1=FR, F2=FR/2, F3=FR/5.

The first second and third processing blocks 1002, 1004, 1006 are similar in structure. As such, only the structure of the first processing block 1002 will be described in detail below.

The first processing block 1002 comprises a first input node 1008, a delay element 1010, a squaring module 1012, a running average module 1014, a first divide-by-two 1016 and a second divide-by-two module 1018 a subtractor 1020 and an adder 1022.

The input node 1008 is coupled to an input of each of the delay element 1010, the subtractor 1020 and the adder 1022. An output of the delay element 1010 is provided to a subtracting input of the subtractor 1020 and an input of the adder 1022. An output of the subtractor 1020 is provided as an input to the squaring module 1012. An output of the squaring module 1012 is provided as an input to the running average module 1014. An output of the running average module 1014 is provided as an input to the first divide-by-two module 1016. An output of the adder 1022 is provided to the second divide-by-two module 1018. An output of the second divide-by-two module 1018 is provided as an input to the second processing block 1004.

As noted above, the first, second and third processing blocks 1002, 1004, 1006 are configured to operate at different frequencies, define by their respective clock inputs C1, C2, C3. The first processing block 1002 may configured to clock in every sample of the digital representation, the second processing block 1004 every 2 samples of the digital representation (i.e. half the rate of the first processing block 1002), and the third processing block 1006 every four samples of the digital representation (i.e. half the rate of the second processing block 1004).

Upon receipt of a sample, the delay element 1010 of the first processing block is configured to apply a delay to the sample and output a delayed sample Qn, which is provided to a subtracting input of the subtractor 1020. The next sample Qn+1 in time is provided to the non-subtracting input of the subtractor 1020. As such, the subtractor 1020 is configured to subtract the n+1th sample Qn+1 in time with the nth sample Qn to obtain a difference between consecutive samples. Th result of this subtraction is provided to the squaring module 1012 which outputs the square of the difference to the running average module 1014. The running average module 1014 performs a running average (or other average) of the result which is the provided to the first divide-by two module 1016. The first divide-by-two module performs a divide-by-two operation which results in the Allan variance for a sample size N of 1 (i.e. N=1).

In addition to outputting the Allan variance for the sample size N=1, the first processing block 1002 is also configured to output the received sample. Since the sample size is 1, this output Ave(n=1) represents the average sample size.

The delayed sample Qn output from the delay element 1010 is additionally provided to the adder 1022 which is configured to add this delayed sample Qn to the sample Qn+1 following the delayed sample Q. As such, consecutive samples are added together at the adder 1022 and output to the second divide-by-two module 1018. The resultant output signal OP1 is an average of two consecutive samples Qn, Qn+1. This output OP1 is then provided as an input to the second processing block 1004.

Since the second processing block 1004 is clocked every two samples (i.e. at half the rate of the first processing block 1002) and the first processing block 1002 is configured to provide an output OP1 which is an average of consecutive samples, the second processing block 1004 is thus configured to clock in every other sample from the output OP1. As such, each sample clocked into the second processing block 1004 represents an average of the last two samples received as an input to the first processing block 1002, i.e. the average of sample size N=2.

The second processing block 1004 then operates in a similar manner to the first processing block 1002. Specifically, the second processing block 1004 outputs an Allan variance for a sample size of N=2. Additionally, the average of two samples received as the input to the second processing bock 1002 may be output as the average value of a sample size N=2 (Ave(N=2). In doing so, processing architecture 1000 obtains the average Ave(N=2) for a sample size N=2 as a biproduct of further calculations required to obtain the Allan variance. It will be appreciated that this average value may be used as a possible result to be output by the processing circuitry 402 of FIG. 5 (i.e. as the mean output MO). Additionally, the second processing block 1004 provides an output OP2 which is an average of two consecutive samples clocked into the second processing block 1004. This output represents the average of the four consecutive samples of the digital representation received at the input of the first processing block 1002. This output OP1 is then provided as an input to the third processing block 1006.

The third processing block 1006 is clocked at half the rate of the second processing block 1006. The third processing block 1006 operates in a similar manner to the first and second processing blocks 1002, 1004 apart from operating at a different (lower rate). The third processing block 1006 thus clocks in every second sample received from the output OP2 of the second processing block 1004 and thus calculates the Allen variance for a sample size N=4. The third processing block 1006 is also configured to output an average Ave(N=4) which represents the average of the four consecutive samples, i.e. an average of sample size N=4. Thus, processing architecture 1000 obtains the average Ave(N=2) for a sample size N=2 as a biproduct of further calculations required to obtain the Allan variance. It will be appreciated that this average value may be used as a possible result to be output by the processing circuitry 402 of FIG. 5 (i.e. as the mean output MO). Additionally, the third processing block 1006 may provide an output signal OP3, for example to additional processing blocks if provided, which is an average of two consecutive samples clocked into the third processing block 1006. This output OP3 represents the average of eight consecutive samples of the digital representation Q received as the input of the first processing block 1002.

Each additional processing block (if provided) may be daisy chained in a similar manner to those shown in FIG. 10, each block being clocked at half the rate of the previous block, such that each block outputs an Allen variance and average for 2^{X-1} samples where X is the number of the respective processing block (i.e. first, second, third etc.).

It will be appreciated that in the architecture 1000 shown in FIG. 10, the delay, squared, and divide-by-two operations represent relatively simple signal processing steps. Calculating a running average represents a more computationally complex operation. Such an operation may be implemented, for example, using a cascaded integrator comb (CIC) filter or another finite impulse response (FIR), such as a IIR low pass filter (e.g. an exponential moving average (EMA) filter).

At any point in time, to determine the optimum sample time T, an evaluation of the minimum of the Allen variance from each of the processing blocks 1102, 1104, 1106 may be ascertained, and the corresponding average value (Ave) used as the mean output MO.

In the embodiments described herein, the electrochemical cell 100 has been described in the form of an electrochemical sensor comprising counter and working electrodes CE, WE (and optionally a reference electrode RE). For such sensors, the stimulus is typically a voltage, and the measured response is a current. It will be appreciated that embodiments of the present disclosure are not limited to such cells and extend to other types of cells, such as electrochemical cells acting as a power source (i.e. a battery) and potentiometric sensors (such as an ion selective electrolyte (ISE) sensor (e.g. a pH meter)). For batteries, potentiometric sensors and the like, the driving stimulus of the cell is typically a current, and the measured response a voltage. Embodiments described above in relation to the amperometric electrochemical cell 100 can equally be applied to cells which are driven with a current, instead of a voltage and for which voltage is the response being measured.

The various circuitry and electrochemical cells described herein may be incorporated into a continuous analyte sensor or a continuous glucose sensor or a continuous glucose monitor. The terms “continuous analyte sensor”, “continuous glucose sensor”, and “continuous glucose monitor” as used herein, will be well-known to a person of ordinary skill in the art and are not to be limited to a special or customized meaning. These terms refer, without limitation, to a device that continuously measures a concentration of an analyte/glucose and/or calibrates the sensor or an electrochemical cell incorporated therein (e.g., by continuously adjusting or determining the sensor's sensitivity and background).

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high-speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general-purpose processor or the like. A module may itself comprise other modules or functional units. A module may be provided by multiple components or sub-modules which need not be co-located and could be provided on different integrated circuits and/or running on different processors.

Embodiments may be implemented in a host device, especially a portable and/or battery powered host device such as a mobile computing device for example a laptop or tablet computer, a games console, a remote control device, a home automation controller or a domestic appliance including a domestic temperature or lighting control system, a toy, a machine such as a robot, an audio player, a video player, or a mobile telephone for example a smartphone.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. Circuitry for processing a response from an electrochemical cell to a stimulus, the circuitry comprising:
sense circuitry configured to measure the response of the electrochemical cell to the stimulus; and
processing circuitry configured to:
sample the measured response to obtain a plurality of samples; and
determine a first average signal based on a first number of samples of the plurality of samples; and
output the first average signal,
wherein the first number of samples in the first average signal is selected to minimise a first variance in the first number of samples.

2. Circuitry of claim 1, wherein the first number of samples is dynamically adjusted to minimize the first variance in the first number of samples.

3. Circuitry of claim 2, wherein the processing circuitry is configured to:
repeat the steps of sampling, determining, and outputting, wherein the first number of samples used to determine the first average signal is selected periodically, wherein a time period between updates of the first number of samples is longer than a time period between repetitions of the steps of sampling, determining, and outputting.

4. Circuitry of claim 1, wherein the processing circuitry is configured to:
in parallel to determining the first average signal, determine one or more second average signals based on one or more second numbers of samples of the plurality of samples, the first number of samples and the one or more second number of samples being different; and
determine a respective second variance in each of the one or more second numbers of samples;
wherein the first number of samples is selected from the first number of samples and the one or more second number of samples, the first variance being lower than each respective second variance.

5. Circuitry of claim 4, wherein the processing circuitry comprises:
a first processing block configured to determine the first average signal and the first variance in the first number of samples; and
one or more second processing blocks, each second processing block configured to determine a respective one of the second average signals and a respective one of the second variances.

6. Circuitry of claim 5, wherein one or more of the first average signal and second average signals are used by others of the first processing block or the one or more second processing blocks for determining a respective first variance or second variance.

7. Circuitry of claim 1, wherein the stimulus comprises a step signal or an impulse signal.

8. Circuitry of claim 1, wherein the processing circuitry comprises further processing circuitry configured to determine a characteristic of the cell based on the first average signal.

9. Circuitry of claim 8, wherein the further processing circuitry is configured to determine, based on the determined characteristic, one or more of the following:
a) an optimum bias voltage to be applied to the electrochemical cell during sensing of an analyte;
b) a quality of an electrolyte in the electrochemical cell;
c) a fault at the electrochemical cell;
d) a condition of the electrochemical cell;
d) determine one or more offsets for subsequent processing;
e) updating an equivalent circuit model (ECM) for the electrochemical cell.

10. Circuitry of claim 9, wherein the condition comprises one or more of:
a) ageing of the electrochemical cell;
b) a change in temperature at the electrochemical cell; and
c) a change in pressure at the electrochemical cell.

11. Circuitry of claim 8, wherein a sample rate or a characteristic of the further processing circuitry is adjusted based on the first number of samples.

12. Circuitry of any claim 1, wherein the first number of samples is selected using a trained neural network.

13. Circuitry of claim 1, wherein the electrochemical cell is an electrochemical sensor, wherein the stimulus is a stimulus voltage, and wherein the measured response is a response current.

14. Circuitry of claim 1, wherein the processing circuitry comprises an analog-to-digital converter (ADC) configured to obtain the plurality of samples.

15. Circuitry of claim 1, further comprising:
drive circuitry configured to apply the stimulus to the electrochemical cell.

16. Circuitry of claim 15, wherein the drive circuitry comprises a digital-to-analog converter configured to generate the stimulus responsive to a digital input signal.

17. Circuitry of claim 1, wherein the electrochemical cell comprises a first electrode and at least one second electrode, wherein the drive circuitry is configured to apply the stimulus to the first electrode, and wherein the sense circuitry is configured to measure the response at the at least one second electrode.

18. Circuitry of claim 17, wherein the electrochemical cell comprises one of an amperometric sensor, a potentiometric sensor and a battery.

19. Circuitry of claim 18 wherein the amperometric sensor comprises a potentiostat, wherein the first electrode comprises a counter electrode of the potentiostat, and wherein the at least one second electrode comprises a working electrode of the potentiostat.

20. A system comprising:
the circuitry of claim 1; and
the electrochemical cell.

21. An electronic device, comprising the circuitry of claim 1.

22. The electronic device of claim 21, wherein the device comprises one of an analyte monitoring device, an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

23. A method of processing a response from an electrochemical cell to a stimulus, the method comprising:
measuring the response of the electrochemical cell to the stimulus; and
sampling the measured response to obtain a plurality of samples; and
determining a first average signal based on a first number of samples of the plurality of samples; and
outputting the first average signal,
wherein the first number of samples in the first average signal is selected to minimise a first variance in the first number of samples.
